(19) United States
(12) Patent Application Publication
(10) Pub. No.: US 2026/0338886 A1
(43) Pub. Date: Oct. 29, 2026

(54) NMR TUBE IDENTIFICATION SYSTEMS AND METHODS

(71) Applicant: Norell, Inc., Morganton, NC (US)

(72) Inventors: Gregory B. Norell, Morganton, NC (US); Scott Ammalathithada, Morganton, NC (US)

(73) Assignee: Norell, Inc., Morganton, NC (US)

(21) Appl. No.: 19/655,870

(22) Filed: Apr. 23, 2026

Related U.S. Application Data
(60) Provisional application No. 63/793,166, filed on Apr. 23, 2025.

(51) Int. Cl. G01R 33/30; G01R 33/00; G06K 7/10

(52) U.S. Cl. CPC G01R 33/30; G01R 33/0052; G06K 7/10712

(57) ABSTRACT

An identification system for nuclear magnetic resonance (NMR) tubes includes a machine-readable identifier formed within a transformed region of a glass body of the NMR tube. The transformed region is created by ion exchange to incorporate metallic ions into the glass, forming a structurally integrated region that enables formation of the identifier within the glass substrate. The identifier is configured to be spectroscopically non-interfering with NMR measurements of a sample contained within the tube. In some configurations, the identifier is disposed on a distal end face of the NMR tube to enable simultaneous scanning of multiple tubes arranged in an array. Systems and methods are also provided for identifying multiple NMR tubes using optical scanning devices, and for manufacturing such tubes through ion exchange, reduction, and selective modification of the transformed region. The identification system provides permanent, solvent-resistant identification while maintaining compatibility with automated workflows and high-throughput sample handling.

### CROSS-REFERENCE TO RELATED APPLICATIONS

The present application claims the benefit of priority to United States Provisional Patent Application Serial No. 63/793,166, filed on Apr. 23, 2025, the entirety of which is incorporated herein by reference.

### BACKGROUND OF THE INVENTION

Nuclear Magnetic Resonance (NMR) spectroscopy is a widely used analytical technique for determining the structure and properties of chemical, biological, and pharmaceutical samples. NMR spectroscopy is relied upon in a variety of applications, including drug discovery, materials science, food analysis, and biomolecular research. Due to the sensitivity of NMR measurements, the integrity and traceability of samples contained within NMR tubes are critical to ensuring accurate and reproducible results.

Despite advancements in NMR instrumentation, automation, and data analysis, sample identification and tracking within NMR workflows remain significant challenges. In many laboratory environments, NMR tubes are identified using rudimentary techniques, such as handwritten markings applied to the exterior of the tube or adhesive labels affixed to the tube surface. These conventional identification approaches present several drawbacks. Handwritten markings can be illegible, inconsistent, or subject to human error. Adhesive labels can detach, degrade, or become damaged when exposed to solvents commonly used in NMR applications, such as chloroform, acetone, and dimethyl sulfoxide (DMSO). As a result, these identification methods can lead to sample misidentification, loss of traceability, and compromised experimental data.

In addition, conventional identification techniques are not well-suited for integration with automated systems. Modern NMR laboratories increasingly rely on automated sample changers, robotic handling systems, and laboratory information management systems (LIMS) to improve throughput and reduce manual intervention. However, the lack of standardized, durable, and machine-readable identifiers on NMR tubes presents a barrier to full automation. In particular, identifiers applied to removable components, such as caps, may not remain associated with the corresponding tube, leading to potential errors in automated workflows.

Attempts have been made to incorporate machine-readable identifiers, such as barcodes or two-dimensional codes, onto sample containers. However, these approaches typically involve applying inks, coatings, or labels to the surface of the container. Such applied materials can introduce foreign substances that may be incompatible with NMR measurements. For example, materials having different magnetic susceptibilities than the glass of the NMR tube can create localized disturbances in the magnetic field, leading to spectral artifacts, baseline distortions, or other measurement inaccuracies. As a result, existing identification approaches often involve a trade-off between identification functionality and preservation of spectroscopic performance.

Furthermore, conventional identification systems are not optimized for high-throughput operation. In many laboratory workflows, individual NMR tubes must be scanned sequentially, which can be time-consuming and prone to error when handling large numbers of samples. Laboratories often process tens to hundreds of samples in a single batch, and manual identification of each tube represents a significant bottleneck. The absence of a system that enables reliable, simultaneous identification of multiple NMR tubes further limits efficiency and scalability.

Accordingly, a need exists for improved systems and methods for identifying NMR tubes that provide permanent, reliable, and machine-readable identification while maintaining compatibility with NMR spectroscopy. There is also a need for identification systems that support automated workflows, enable high-throughput processing, and ensure that identifiers remain permanently associated with the corresponding NMR tubes throughout handling, analysis, and data management processes.

### BRIEF SUMMARY OF THE INVENTION

The present disclosure is directed to systems and methods for identification of nuclear magnetic resonance (NMR) tubes and other analytical sample containers. The disclosed systems provide permanent, machine-readable identification that is integrated within the structure of the container while maintaining compatibility with NMR spectroscopy and automated workflows.

In one aspect, the present disclosure provides an NMR tube comprising an elongated glass body extending from a proximal end to a distal end and a first machine-readable identifier formed within a transformed region of the glass body. The transformed region comprises a portion of the glass body that has undergone ion exchange to incorporate metallic ions into the glass body, and the first machine-readable identifier is integral with the glass body. The first machine-readable identifier is configured to be spectroscopically non-interfering with NMR measurements performed on a sample contained within the NMR tube.

In another aspect, the present disclosure provides a system for identifying a plurality of NMR tubes. The system comprises a plurality of NMR tubes, each including a machine-readable identifier formed within a transformed region of the glass body, and a scanning device configured to read the machine-readable identifiers from distal end faces of the plurality of NMR tubes while the plurality of NMR tubes remain arranged in a common orientation. This configuration enables simultaneous identification of multiple NMR tubes in a high-throughput environment.

In a further aspect, the present disclosure provides a method of identifying a plurality of NMR tubes. The method comprises providing a plurality of NMR tubes having machine-readable identifiers formed within transformed regions of the tubes, arranging the plurality of NMR tubes such that distal end faces of the tubes are oriented in a common direction, and simultaneously scanning the machine-readable identifiers from the distal end faces using a scanning device.

In another aspect, the present disclosure provides a method of manufacturing an NMR tube having a machine-readable identifier. The method comprises applying a metal-containing composition to a surface of a glass body, thermally processing the glass body to cause ions of the metal composition to diffuse into the glass body via ion exchange, reducing the ions within the glass body to form metallic nanoparticles and thereby form a transformed region within the glass body, and forming a machine-readable identifier within the transformed region by selectively modifying the transformed region. The machine-readable identifier is formed such that it is spectroscopically non-interfering with NMR measurements performed on a sample contained within the NMR tube.

In a further aspect, the present disclosure provides a container for storing a sample. The container comprises a body formed of a substrate material and a machine-readable identifier formed within a transformed region of the substrate material. The transformed region comprises a region of the substrate material that has undergone ion exchange to incorporate metallic ions into the substrate material and contains metallic nanoparticles within the substrate material, and the machine-readable identifier is integral with the substrate material and resistant to degradation upon exposure to solvents.

### BRIEF DESCRIPTION OF THE DRAWINGS

The present invention will become more fully understood from the detailed description and the accompanying drawings, wherein:

FIG. 1 is a top perspective view of an NMR tube including an identification system in accordance with an embodiment of the present disclosure;

FIG. 2 is a bottom perspective view of the NMR tube of FIG. 1 illustrating a first machine-readable identifier disposed on a distal end face of the NMR tube;

FIG. 3 is a side view of the NMR tube of FIG. 1 illustrating a second machine-readable identifier disposed on an outer surface of the NMR tube;

FIG. 4 is a detail view of area I of FIG. 2;

FIG. 5 is a bottom perspective view of a plurality of NMR tubes of FIG. 1 positioned in a tube rack;

FIG. 6 is a schematic diagram of a system for identifying NMR tubes including an NMR tube rack, a scanning device, and a data processing system; and

FIG. 7 is a flow diagram illustrating a method of manufacturing an NMR tube having a machine-readable identifier in accordance with an embodiment of the present disclosure.

### DETAILED DESCRIPTION

Before the present devices, systems, and methods are described, it is to be understood that the present disclosure is not limited to the particular processes, compositions, or methodologies described, as these may vary. It is also to be understood that the terminology used in the description is for the purposes of describing the particular versions or embodiments only, and is not intended to limit the scope of the present disclosure.

Unless defined otherwise, all technical and scientific terms used herein have the same meanings as commonly understood by one of ordinary skill in the art. Although any methods and materials similar or equivalent to those described herein can be used in the practice or testing of embodiments of the present disclosure, the methods, devices, and materials in some embodiments are now described. All publications disclosed herein are incorporated by reference in their entireties. Nothing herein is to be construed as an admission that the present disclosure is not entitled to antedate such disclosure by virtue of prior invention.

The indefinite articles “a” and “an,” as used herein in the specification and in the claims, unless clearly indicated to the contrary, should be understood to mean “at least one.” The phrase “and/or,” as used herein in the specification and in the claims, should be understood to mean “either or both” of the elements so conjoined, i.e., elements that are conjunctively present in some cases and disjunctively present in other cases. Other elements may optionally be present other than the elements specifically identified by the “and/or” clause, whether related or unrelated to those elements specifically identified unless clearly indicated to the contrary. Thus, as a non-limiting example, a reference to “A and/or B,” when used in conjunction with open-ended language such as “comprising” can refer, in one embodiment, to A without B (optionally including elements other than B); in another embodiment, to B without A (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, “either,” “one of,” “only one of,” or “exactly one of.” “Consisting essentially of,” when used in the claims, shall have its ordinary meaning as used in the field of patent law.

The term “about” is used herein to mean within the typical ranges of tolerances in the art. For example, “about” can be understood as about 2 standard deviations from the mean. According to certain embodiments, when referring to a measurable value such as an amount and the like, “about” is meant to encompass variations of ±20%, ±10%, ±5%, ±1%, ±0.9%, ±0.8%, ±0.7%, ±0.6%, ±0.5%, ±0.4%, ±0.3%, ±0.2% or ±0.1% from the specified value as such variations are appropriate to perform the disclosed methods. When “about” is present before a series of numbers or a range, it is understood that “about” can modify each of the numbers in the series or range. In some embodiments herein, a value or range of values prefaced with “about” includes the value or ranges of values without the modifier “about.”

The term “at least” prior to a number or series of numbers (e.g. “at least two”) is understood to include the number adjacent to the term “at least,” and all subsequent numbers or integers that could logically be included, as clear from context. When “at least” is present before a series of numbers or a range, it is understood that “at least” can modify each of the numbers in the series or range. Ranges provided herein are understood to include all individual integer values and all subranges within the ranges.

As used herein, the terms “comprising” (and any form of comprising, such as “comprise,” “comprises,” and “comprised”), “having” (and any form of having, such as “have” and “has”), “including” (and any form of including, such as “includes” and “include”), or “containing” (and any form of containing, such as “contains” and “contain”), are inclusive or open-ended and do not exclude additional, unrecited elements or method steps.

The description of illustrative embodiments according to principles of the present invention is intended to be read in connection with the accompanying drawings, which are to be considered part of the entire written description. In the description of embodiments of the invention disclosed herein, any reference to direction or orientation is merely intended for convenience of description and is not intended in any way to limit the scope of the present invention. Relative terms such as “lower,” “upper,” “horizontal,” “vertical,” “above,” “below,” “up,” “down,” “left,” “right,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation unless explicitly indicated as such.

Terms such as “attached,” “affixed,” “connected,” “coupled,” “interconnected,” and similar refer to a relationship wherein structures are secured or attached to one another either directly or indirectly through intervening structures, as well as both movable or rigid attachments or relationships, unless expressly described otherwise. Moreover, the features and benefits of the invention are illustrated by reference to the preferred embodiments. Accordingly, the invention expressly should not be limited to such preferred embodiments illustrating some possible non-limiting combinations of features that may exist alone or in other combinations of features; the scope of the invention being defined by the claims appended hereto.

Features of the present invention(s) may be implemented in software, hardware, firmware, or combinations thereof. In particular, the various units that form a part of the control circuit described herein may comprise software, hardware, firmware, and combinations thereof. Each such “unit” may comprise its own processor, or it may be coupled to a processor that is used for all components of the control circuit, or some combination of this may occur. The computer programs described herein are not limited to any particular embodiment, and may be implemented in an operating system, application program, foreground or background processes, driver, or any combination thereof. The computer programs may be executed on a single computer or server processor or multiple computer or server processors.

Processors (also referred to as controllers or control units) described herein may be any central processing unit (CPU), microprocessor, micro-controller, computational, or programmable device or circuit configured for executing computer program instructions (e.g., code). Various processors may be embodied in computer and/or server hardware of any suitable type (e.g., desktop, laptop, notebook, tablets, cellular phones, etc.) and may include all the usual ancillary components necessary to form a functional data processing device including without limitation a bus, software and data storage such as volatile and non-volatile memory, input/output devices, graphical user interfaces (GUIs), removable data storage, and wired and/or wireless communication interface devices including Wi-Fi, Bluetooth, LAN, etc. In one particular embodiment, a processor unit may reside on the device (snare device as described herein) itself and all processing can be done internally and integrally on the device without limitation and without the need of any outside resource.

Computer-executable instructions or programs (e.g., software or code) and data described herein may be programmed into and tangibly embodied in a non-transitory computer-readable medium that is accessible to and retrievable by a respective processor as described herein which configures and directs the processor to perform the desired functions and processes by executing the instructions encoded in the medium. A device embodying a programmable processor configured to such non-transitory computer-executable instructions or programs may be referred to as a “programmable device,” or “device,” and multiple programmable devices in mutual communication may be referred to as a “programmable system.” It should be noted that non-transitory “computer-readable medium” as described herein may include, without limitation, any suitable volatile or non-volatile memory including random access memory (RAM) and various types thereof, read-only memory (ROM) and various types thereof, USB flash memory, and magnetic or optical data storage devices (e.g., internal/external hard disks, floppy discs, magnetic tape CD-ROM, DVD-ROM, optical disk, ZIP™ drive, Blu-ray disk, and others), which may be written to and/or read by a processor operably connected to the medium.

In some embodiments, the present invention(s) may be embodied in the form of computer-implemented processes and apparatuses such as processor-based data processing and communication systems or computer systems for practicing those processes. The present invention(s) may also be embodied in the form of software or computer program code embodied in a non-transitory computer-readable storage medium, which when loaded into and executed by the data processing and communications systems or computer systems, the computer program code segments configure the processor to create specific logic circuits configured for implementing the processes.

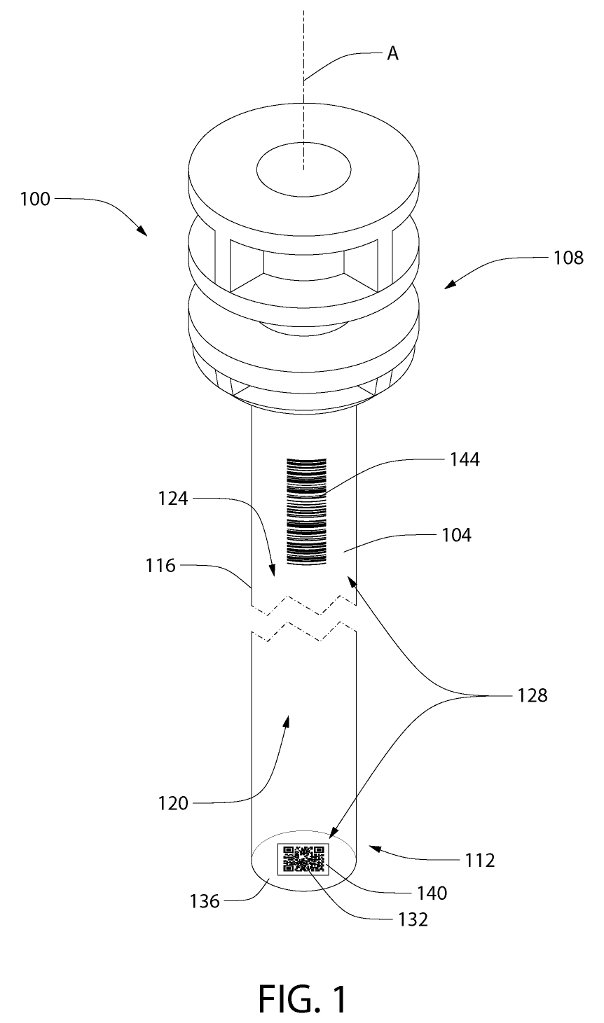

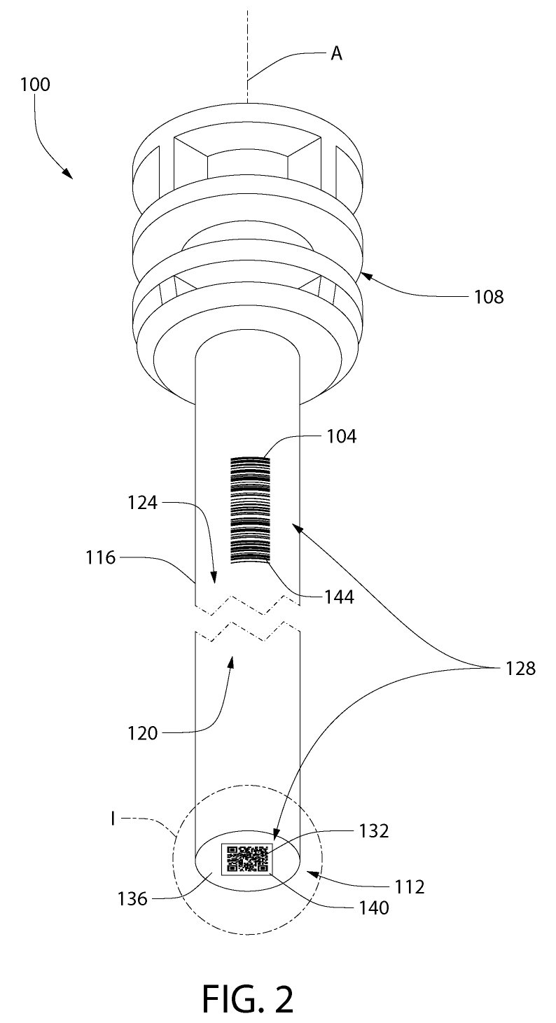

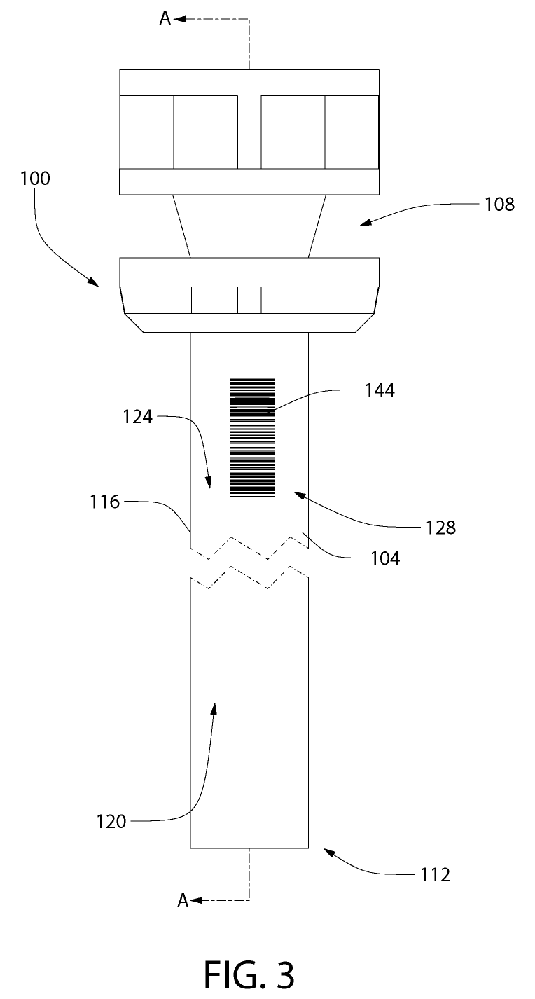

Referring now generally to FIGS. 1–3, an NMR tube 100 is illustrated in accordance with an exemplary embodiment of the present disclosure. The NMR tube 100 comprises an elongated body 104 extending along a longitudinal axis A-A from a proximal end 108 to a distal end 112. The elongated body 104 comprises an outer surface 116 and an inner surface 120, the inner surface 120 defining a tube cavity 124 configured to receive and contain a liquid sample for analysis by a nuclear magnetic resonance (NMR) spectrometer.

The NMR tube 100 further comprises an identification system 128 configured to provide machine-readable identification of the NMR tube 100. The identification system 128 includes at least a first machine-readable identifier 132 formed at or adjacent to the distal end 112 of the elongated body 104. In the illustrated embodiment, the first machine-readable identifier 132 is positioned on a distal end face 136 of the NMR tube 100, the distal end face 136 forming a generally planar bottom surface of the NMR tube 100.

In accordance with a key aspect of the present disclosure, the first machine-readable identifier 132 is formed within a transformed region 140 of the elongated body 104. The transformed region 140 comprises a portion of the glass material of the elongated body 104 that has undergone a material transformation process, such as ion exchange, to alter the structural and optical properties of the glass. As described in greater detail below, the transformed region 140 is integrally formed within the glass matrix of the elongated body 104 rather than being applied as a separate layer, coating, or label.

Because the first machine-readable identifier 132 is formed within the transformed region 140, the identifier 132 is permanently integrated into the structure of the NMR tube 100. This configuration provides a number of significant advantages over conventional identification techniques, such as adhesive labels, ink-based markings, or identifiers applied to removable components (e.g., caps). For example, the embedded identifier 132 is resistant to degradation, detachment, or loss, even when exposed to aggressive solvents commonly used in NMR applications, such as chloroform, acetone, and dimethyl sulfoxide (DMSO).

Furthermore, because the identifier 132 is formed within the glass matrix of the NMR tube 100 rather than as a foreign material on the surface, the identifier 132 is configured to be spectroscopically non-interfering with NMR measurements performed on a sample contained within the tube cavity 124. In particular, the transformed region 140 and the associated identifier 132 do not introduce detectable artifacts, distortions, or magnetic susceptibility variations that would adversely affect NMR spectral quality. Thus, the identifier 132 is readable by optical scanning systems while remaining effectively undetectable during NMR analysis.

In addition to preserving spectral integrity, the identification system 128 enables integration of the NMR tube 100 into automated workflows. In particular, the positioning of the first machine-readable identifier 132 on the distal end face 136 enables simultaneous scanning of multiple NMR tubes 100 when arranged in a defined array of NMR tubes, such as within a multi-position tray or rack. This configuration significantly improves throughput and reduces the risk of human error associated with manual identification.

Additionally, the identifier 132 remains associated with the NMR tube 100 regardless of the presence or absence of removable components. In conventional systems, identifiers are often placed on caps or other removable elements, which can be inadvertently separated from the tube, leading to misidentification. By embedding the identifier 132 directly into the NMR tube 100, the present system ensures that the identifier always follows the sample, thereby improving traceability and chain-of-custody integrity.

Overall, the NMR tube 100 with the integrated identification system 128 provides a robust, permanent, and automation-compatible solution for sample identification in NMR workflows and other analytical applications. The combination of embedded identifiers, material-level integration, and spectroscopic compatibility represents a significant advancement over existing approaches, enabling improved data integrity, increased throughput, and enhanced reliability in both manual and automated laboratory environments.

Continuing with FIGS. 1–3, the structural configuration of the NMR tube 100 and the identification system 128 will now be described in greater detail. The elongated body 104 of the NMR tube 100 extends along the longitudinal axis A-A between the proximal end 108 and the distal end 112 and is generally cylindrical in shape. The outer surface 116 of the elongated body 104 defines an external profile configured to be compatible with standard NMR instrumentation and automated sample handling systems, while the inner surface 120 defines the tube cavity 124 configured to contain a liquid sample.

The elongated body 104 has a substantially constant outer diameter along its length, and the tube cavity 124 has a substantially constant inner diameter. The dimensions of the NMR tube 100 are selected to be compatible with NMR spectroscopy systems and associated sample handling equipment. In some embodiments, the elongated body 104 has an outer diameter in a range from about 0.5 mm to about 5.0 mm, including from about 0.8 mm to about 2.0 mm, and further including from about 0.9 mm to about 1.8 mm. In some embodiments, the outer diameter is approximately 1.0 mm or approximately 1.7 mm. In some embodiments, the tube cavity 124 has an inner diameter in a range from about 0.3 mm to about 3.0 mm, including from about 0.5 mm to about 1.5 mm, and further including from about 0.6 mm to about 1.3 mm. In some embodiments, the elongated body 104 has a length in a range from about 5 cm to about 15 cm, including from about 6 cm to about 12 cm, and further including from about 7 cm to about 10 cm.

The distal end 112 of the elongated body 104 comprises the distal end face 136, which forms a closed bottom surface of the NMR tube 100. The distal end face 136 provides a surface suitable for formation and optical detection of the first machine-readable identifier 132. In some embodiments, the distal end face 136 is substantially planar and oriented perpendicular to the longitudinal axis A-A. In other embodiments, the distal end face 136 includes a slightly curved, recessed, or otherwise contoured geometry, provided that the first machine-readable identifier 132 remains optically accessible for scanning.

The first machine-readable identifier 132 is disposed on or within the distal end face 136 of the NMR tube 100. The first machine-readable identifier 132 is positioned to enable reliable optical detection and alignment during scanning operations. In some embodiments, the first machine-readable identifier 132 is located at a central portion of the distal end face 136. In other embodiments, the first machine-readable identifier 132 is offset from the center or distributed across the distal end face 136 to optimize scanning performance, error correction, or encoding density.

The identification system 128 further comprises a second machine-readable identifier 144 disposed on the outer surface 116 of the elongated body 104. The second machine-readable identifier 144 is positioned along a sidewall region of the elongated body 104 to facilitate individual identification of the NMR tube 100 during manual handling or automated processing. In some embodiments, the second machine-readable identifier 144 is located adjacent to the proximal end 108. In some embodiments, the second machine-readable identifier 144 extends longitudinally along the outer surface 116, while in other embodiments the second machine-readable identifier 144 extends circumferentially or is oriented at an angle relative to the longitudinal axis A-A.

The first machine-readable identifier 132 and the second machine-readable identifier 144 are configured to provide complementary identification functionality. The first machine-readable identifier 132 is configured for simultaneous or batch scanning of a plurality of NMR tubes 100 when arranged in a defined array, while the second machine-readable identifier 144 is configured for individual scanning of a single NMR tube 100. In some embodiments, the first machine-readable identifier 132 and the second machine-readable identifier 144 encode identical information corresponding to the NMR tube 100. In other embodiments, the first machine-readable identifier 132 and the second machine-readable identifier 144 encode different but related information.

The machine-readable identifiers 132, 140 comprise codes that are readable by optical scanning systems. In some embodiments, the first machine-readable identifier 132 comprises a two-dimensional code, such as a data matrix code, QR code, or other matrix symbology. In some embodiments, the second machine-readable identifier 144 comprises a one-dimensional barcode. In other embodiments, either or both of the first machine-readable identifiers 132, 140 comprise two-dimensional codes, one-dimensional codes, alphanumeric characters, or combinations thereof. In some embodiments, human-readable characters are provided adjacent to or integrated with one or more of the machine-readable identifiers 132, 140.

The size and configuration of the first machine-readable identifier 132 are selected to fit within the distal end face 136 while maintaining sufficient resolution and contrast for reliable optical detection. The encoding capacity, module size, and error correction capability of the first machine-readable identifier 132 are selected based on the available surface area and the desired information content. The second machine-readable identifier 144 is dimensioned and positioned to remain visible and accessible during handling and scanning operations.

In some embodiments, a plurality of second machine-readable identifiers 140 are provided at different circumferential positions along the outer surface 116 to enable scanning from multiple orientations. In some embodiments, such redundancy ensures that at least one of the second machine-readable identifiers 140 remains accessible for scanning regardless of the rotational orientation of the NMR tube 100.

The machine-readable identifiers 132, 140 are configured to be read by optical scanning systems, including barcode scanners, imaging systems, and machine vision systems. The positioning of the first machine-readable identifier 132 on the distal end face 136 enables simultaneous scanning of multiple NMR tubes 100 when arranged in a defined array, such as a multi-position tray or rack, thereby enabling high-throughput identification.

The identification system 128 is configured such that the first machine-readable identifier 132 is permanently associated with the NMR tube 100 and is not removable or transferable to another tube. This configuration ensures that the identity of the NMR tube 100 remains coupled to the physical tube regardless of handling or processing, thereby improving traceability and reducing the risk of misidentification.

In some embodiments, auxiliary components associated with the NMR tube 100, such as caps, closures, or handling fixtures (not shown), include additional machine-readable identifiers. In some embodiments, such additional identifiers provide supplementary identification functionality. However, the first machine-readable identifier 132 formed within the elongated body 104 serves as a primary identifier that remains permanently associated with the NMR tube 100.

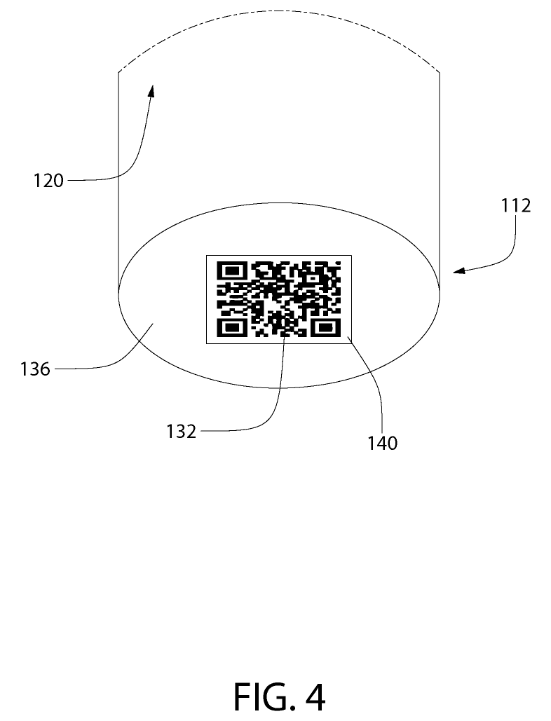

Referring now to FIG. 4, and with continued reference to the NMR tube 100 described above, the transformed region 140 in which the first machine-readable identifier 132 is formed will now be described in greater detail. The transformed region 140 comprises a portion of the elongated body 104 in which the material properties of the glass have been modified relative to untreated regions of the elongated body 104.

The elongated body 104 is formed from a glass material, such as borosilicate glass, fused silica, or other glass compositions suitable for NMR applications. The transformed region 140 is formed within the glass matrix of the elongated body 104 through a material transformation process that alters the composition, structure, and optical properties of the glass in a localized region. In particular, the transformed region 140 is not a surface coating or applied layer, but rather a structurally integrated region within the glass substrate.

The transformed region 140 is formed through an ion exchange process in which ions are introduced into the glass matrix of the elongated body 104. In this process, ions from an external source diffuse into the glass and replace native ions present in the glass composition, such as alkali metal ions. This ion exchange process results in a modified glass region having different chemical and physical properties relative to the surrounding untreated glass.

The ions introduced into the glass matrix comprise metallic ions. In some embodiments, the metallic ions comprise silver ions. In other embodiments, the metallic ions comprise other metal species capable of participating in ion exchange and subsequent transformation processes, including, for example, copper, gold, or other transition metal ions. The selection of the metallic ions is based on the ability to modify the optical absorption properties of the glass and to facilitate subsequent formation of the machine-readable identifier 132.

Following ion exchange, the transformed region 140 undergoes a reduction process in which the metallic ions are converted into metallic nanoparticles within the glass matrix. The metallic nanoparticles are distributed within the transformed region 140 and are embedded within the glass structure. The formation of the metallic nanoparticles results in a region having altered optical properties relative to untreated glass, including increased absorption of electromagnetic radiation at selected wavelengths.

The transformed region 140 extends into the elongated body 104 to a controlled depth measured from the outer surface 116 or the distal end face 136. In some embodiments, the transformed region 140 has a depth in a range from about 5 microns to about 100 microns, including from about 10 microns to about 50 microns. The depth of the transformed region 140 is selected to provide sufficient optical contrast for formation and detection of the machine-readable identifier 132 while maintaining the structural integrity and functional performance of the NMR tube 100.

The transformed region 140 exhibits optical properties that differ from those of untreated glass. In particular, the presence of the metallic nanoparticles results in enhanced absorption of electromagnetic radiation, including ultraviolet (UV) radiation, relative to untreated regions of the elongated body 104. This enhanced absorption enables precise and controlled modification of the transformed region 140 during formation of the machine-readable identifier 132, as described in further detail below.

The transformed region 140 is formed such that the structural integrity of the elongated body 104 is preserved. The ion exchange and reduction processes are controlled to avoid the formation of defects, such as microfractures, voids, or stress concentrations, within the glass. As a result, the transformed region 140 maintains the mechanical strength and dimensional stability required for use of the NMR tube 100 in analytical instrumentation.

Because the transformed region 140 is integrated within the glass matrix of the elongated body 104, the transformed region 140 does not form a discrete interface between different materials. This absence of a material interface contributes to the spectroscopic compatibility of the NMR tube 100, as the transformed region 140 does not introduce discontinuities or foreign materials that would otherwise affect NMR measurements.

In some embodiments, the transformed region 140 is formed selectively at one or more locations on the elongated body 104, including at the distal end face 136 and, in some embodiments, at one or more sidewall regions corresponding to the location of the second machine-readable identifier 144. In other embodiments, multiple transformed regions 144 are formed at different locations on the NMR tube 100 to support multiple identifiers or additional functional features.

In some embodiments, the properties of the transformed region 140 are controlled by adjusting process parameters associated with the ion exchange and reduction processes. Such parameters include temperature, duration of thermal processing, concentration of the metal-containing composition, and composition of the glass. By controlling these parameters, the depth, optical density, and distribution of the metallic nanoparticles within the transformed region 140 can be tailored to achieve desired performance characteristics.

The transformed region 140 provides a substrate that is particularly well-suited for formation of high-contrast, high-resolution machine-readable identifiers. The combination of enhanced optical absorption, structural integration within the glass matrix, and controlled material properties enables reliable formation and long-term stability of the machine-readable identifier 132 under a wide range of environmental and operational conditions.

Continuing with FIG. 4, the formation of the first machine-readable identifier 132 within the transformed region 140 will now be described in greater detail. The first machine-readable identifier 132 is formed by selectively modifying portions of the transformed region 140 to create a machine-readable pattern having sufficient contrast for optical detection.

The first machine-readable identifier 132 is formed by applying energy to the transformed region 140 in a controlled manner to locally alter the optical properties of the transformed region 140. In particular, portions of the transformed region 140 are selectively modified to create regions of differing optical contrast that collectively define the machine-readable pattern.

In some embodiments, the first machine-readable identifier 132 is formed by selectively removing portions of the transformed region 140. In some embodiments, the removal of portions of the transformed region 140 exposes underlying regions of the elongated body 104 having different optical properties, thereby creating a high-contrast pattern between modified and unmodified regions.

In some embodiments, the selective modification of the transformed region 140 is performed using a laser. In some embodiments, the laser comprises an ultraviolet (UV) laser configured to interact with the transformed region 140. In other embodiments, other laser types are utilized, including infrared (IR) lasers, green lasers, excimer lasers, or other laser systems selected based on the absorption characteristics of the transformed region 140 and the desired marking resolution.

The transformed region 140 exhibits enhanced absorption of electromagnetic radiation relative to untreated glass, which enables the laser energy to be absorbed at or near the surface of the transformed region 140. As a result, the laser operates effectively at lower energy levels compared to conventional laser marking of untreated glass. This localized absorption enables precise modification of the transformed region 140 without transmitting significant energy into the bulk of the elongated body 104.

The selective modification of the transformed region 140 is performed with a level of precision sufficient to produce machine-readable features at a microscopic scale. In some embodiments, the resulting pattern comprises a plurality of discrete elements, such as modules, bars, or pixels, arranged to encode information in a machine-readable format. The dimensions and spacing of these elements are selected to be compatible with optical scanning systems.

The use of the transformed region 140 for formation of the first machine-readable identifier 132 provides significant advantages over conventional laser marking of untreated glass. In conventional systems, glass is substantially transparent to many laser wavelengths, resulting in scattering of the laser energy within the glass and requiring higher energy levels to achieve marking. These higher energy levels can introduce defects, such as microfractures or internal damage, within the glass structure.

In contrast, the transformed region 140 absorbs the laser energy at or near the surface, which reduces scattering and confines the energy to the intended modification region. This controlled interaction enables the formation of sharply defined features with high contrast while preserving the structural integrity of the elongated body 104.

The formation of the first machine-readable identifier 132 is performed such that the mechanical and functional properties of the NMR tube 100 are maintained. In particular, the selective modification of the transformed region 140 is controlled to avoid the introduction of structural defects that could compromise the strength, dimensional stability, or performance of the NMR tube 100 during use.

In some embodiments, the laser operates at reduced energy levels relative to those required for marking untreated glass, due to the enhanced absorption characteristics of the transformed region 140. This reduced energy operation contributes to improved process efficiency, reduced risk of damage, and increased consistency of the resulting machine-readable identifier 132.

In some embodiments, the selective modification of the transformed region 140 comprises laser ablation of portions of the transformed region 140 to form the machine-readable pattern. In other embodiments, the modification comprises localized alteration of the transformed region 140 without complete removal of material, such as through controlled changes in material structure or optical properties.

The formation process for the first machine-readable identifier 132 is compatible with high-throughput manufacturing techniques. In some embodiments, the laser modification process is automated and integrated into a production line, enabling consistent and repeatable formation of machine-readable identifiers across large numbers of NMR tubes 100.

In some embodiments, the second machine-readable identifier 144 is formed using the same or similar process as the first machine-readable identifier 132. In other embodiments, the second machine-readable identifier 144 is formed using alternative techniques, including printing, coating, or application of labels. In such embodiments, the first machine-readable identifier 132 remains the primary identifier due to its permanent integration within the elongated body 104.

The resulting machine-readable identifier 132 is permanently integrated into the NMR tube 100 and remains stable under conditions encountered during storage, handling, and use. The identifier 132 retains its readability and contrast after exposure to chemical solvents, mechanical handling, and environmental conditions typical of laboratory workflows.

The NMR tube 100 and the identification system 128 are configured such that the presence of the first machine-readable identifier 132 does not interfere with nuclear magnetic resonance (NMR) measurements performed on a sample contained within the tube cavity 124. In particular, the first machine-readable identifier 132 is configured to be spectroscopically non-interfering during operation of an NMR spectrometer.

As described above, the first machine-readable identifier 132 is formed within the transformed region 140, which is integrally formed within the glass matrix of the elongated body 104. Because the transformed region 140 is part of the glass substrate rather than a separate material applied to the surface, the transformed region 140 does not introduce a discrete interface between dissimilar materials. The absence of such an interface reduces the likelihood of localized variations in magnetic susceptibility that could otherwise affect NMR measurements.

The material properties of the transformed region 140 are selected and controlled such that the transformed region 140 does not produce detectable artifacts in an NMR spectrum. In particular, the transformed region 140 does not introduce distortions in spectral baselines, does not generate spurious peaks, and does not interfere with shimming processes used to homogenize the magnetic field during NMR analysis.

The formation of the first machine-readable identifier 132 within the transformed region 140 is controlled to preserve the structural continuity of the elongated body 104. As a result, the local modifications associated with the identifier 132 do not create voids, inclusions, or discontinuities that would alter the magnetic field experienced by the sample within the tube cavity 124. The structural integrity of the elongated body 104 is maintained such that the NMR tube 100 continues to perform equivalently to an unmodified NMR tube during spectroscopic analysis.

The elimination of spectroscopic interference is particularly significant in NMR applications due to the sensitivity of NMR measurements to variations in material properties. Conventional identification approaches, such as adhesive labels, printed inks, or coatings applied to the surface of a tube, can introduce foreign materials that have different magnetic susceptibilities than the underlying glass. These differences can result in measurable artifacts, including line broadening, baseline distortion, and errors in spectral interpretation.

By contrast, the identification system 128 described herein avoids the use of foreign materials at the location of the first machine-readable identifier 132. The identifier 132 is formed within the glass itself, thereby maintaining a substantially uniform material composition in the vicinity of the tube cavity 124. This uniformity enables the NMR tube 100 to maintain high spectral quality and measurement accuracy.

The spectroscopic compatibility of the identification system 128 enables the NMR tube 100 to be used in high-precision analytical applications without compromising data quality. The NMR tube 100 is suitable for use in applications requiring high-resolution NMR spectroscopy, including chemical analysis, pharmaceutical research, and biomolecular studies.

In some embodiments, the transformed region 140 and the first machine-readable identifier 132 are configured such that the presence of the identifier 132 is not detectable by an NMR spectrometer during operation. In some embodiments, the identifier 132 does not produce any measurable change in the NMR signal relative to an otherwise identical NMR tube without the identifier.

The combination of structural integration, controlled material transformation, and precision formation of the first machine-readable identifier 132 enables the identification system 128 to provide reliable machine-readable identification while preserving the functional performance of the NMR tube 100. This capability represents a significant improvement over conventional identification techniques, which typically involve trade-offs between identification functionality and spectroscopic performance.

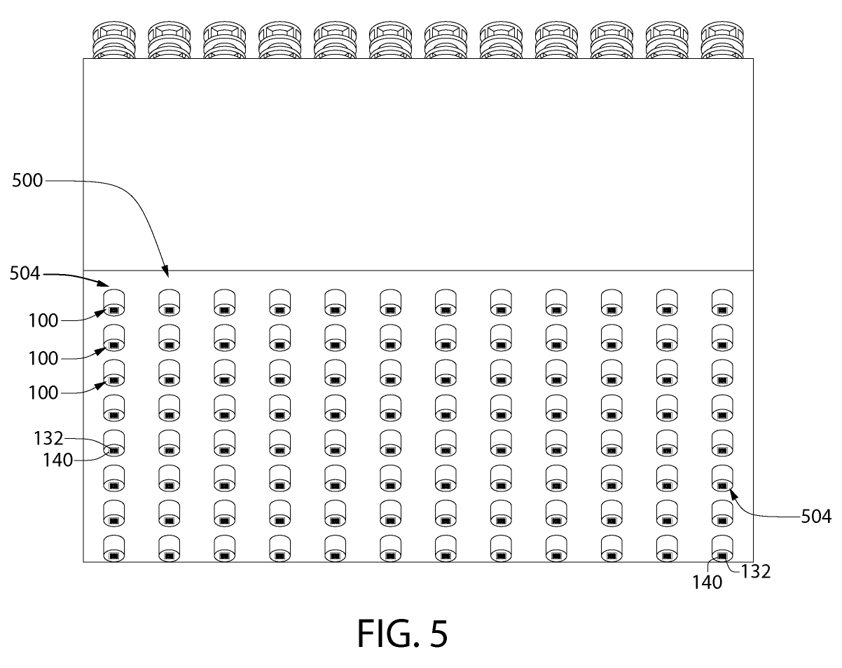

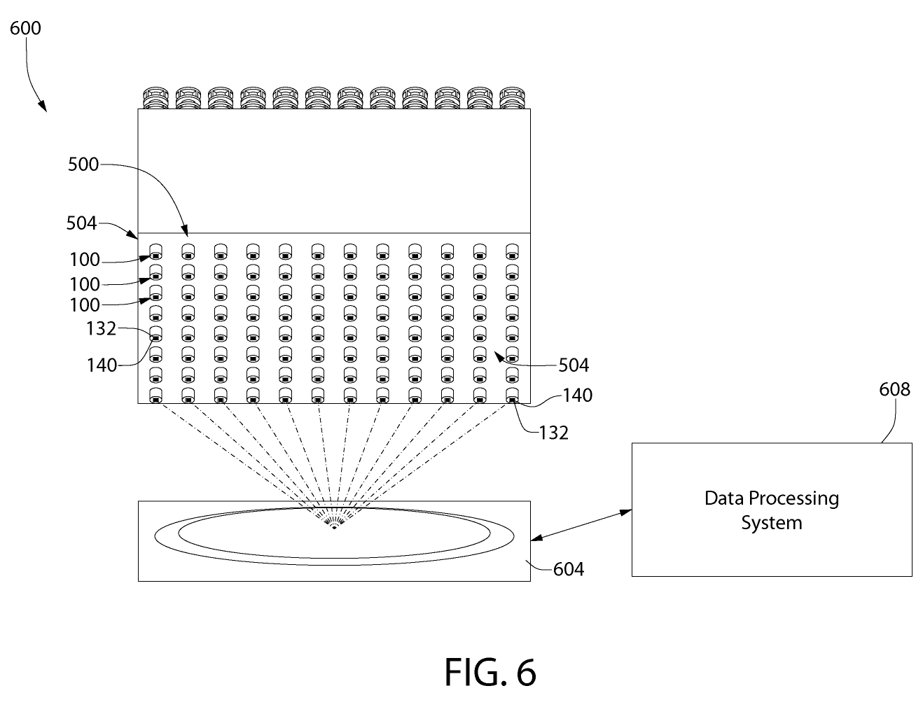

Referring to FIGS. 5-6, the NMR tube 100 and the identification system 128 are configured for use in systems that enable high-throughput identification, tracking, and processing of multiple samples. In particular, the positioning of the first machine-readable identifier 132 on the distal end face 136 enables simultaneous optical detection of a plurality of NMR tubes 100 when the NMR tubes 100 are arranged in a defined array.

Continuing with FIG. 5, the plurality of NMR tubes 100 are positioned in a support structure 500 configured to maintain the NMR tubes 100 in a defined spatial arrangement. The support structure 500 comprises a multi-position tray or rack having a plurality of receptacles 504, each receptacle 504 configured to receive and support one of the NMR tubes 100. The receptacles 504 are arranged in a predefined array that maintains consistent spacing and alignment between the NMR tubes 100.

In some embodiments, the support structure 500 comprises a tray having a standard multi-well format. In some embodiments, the support structure 500 comprises a 96-position tray arranged in an 8×12 matrix. In other embodiments, the support structure 500 comprises trays having other configurations, including 24-position, 48-position, 384-position, or other array formats. The spacing and layout of the receptacles 504 are selected to be compatible with automated laboratory equipment, including liquid handling systems and analytical instruments.

Continuing with FIG. 6, a system 600 for identifying a plurality of NMR tubes 100 is illustrated. The system 600 comprises a plurality of NMR tubes 100 and a scanning device 604 configured to read the first machine-readable identifiers 132 from the distal end faces 136 of the plurality of NMR tubes 100. The plurality of NMR tubes 100 are arranged such that the distal end faces 136 are oriented in a common direction, thereby enabling the scanning device 604 to simultaneously capture the machine-readable identifiers 132 from multiple NMR tubes 100.

The scanning device 604 comprises an optical scanning system configured to detect and decode the machine-readable identifiers 132. The scanning device 604 comprises, in some embodiments, a barcode scanner, an imaging system, or a machine vision system. The scanning device 604 is positioned relative to the support structure 500 such that a field of view of the scanning device 604 encompasses the distal end faces 136 of multiple NMR tubes 100 simultaneously.

The configuration of the system 600 enables simultaneous scanning of a plurality of NMR tubes 100 in a single operation. This batch scanning capability significantly reduces the time required to identify and process multiple samples compared to conventional approaches in which individual tubes are scanned sequentially. The ability to scan multiple NMR tubes 100 at once improves throughput and reduces the likelihood of errors associated with manual handling and identification.

The system 600 further comprises a data processing system 608 configured to receive data from the scanning device 604. The data processing system 608 associates the machine-readable identifiers 132 with corresponding sample information. In some embodiments, the data processing system 608 comprises a database configured to store information associated with each NMR tube 100, including sample identity, experimental parameters, and analysis results.

In some embodiments, the data processing system 608 is integrated with a laboratory information management system (LIMS). The LIMS is configured to track samples throughout a workflow, including sample preparation, analysis, and data storage. The integration of the identification system 128 with the LIMS enables automated tracking of samples and reduces the risk of misidentification or data entry errors.

The system 600 supports workflows in which NMR tubes 100 are processed in batches. For example, a plurality of NMR tubes 100 are placed in the support structure 500 and scanned using the scanning device 604 to identify each tube. The identified tubes are then processed, analyzed, or transported as a group. The ability to identify multiple tubes simultaneously enables efficient handling of large numbers of samples in high-throughput laboratory environments.

The second machine-readable identifier 144 provides additional flexibility in system operation. When an individual NMR tube 100 is removed from the support structure 500, the second machine-readable identifier 144 on the outer surface 116 can be scanned independently using a handheld scanner or other scanning device. This enables identification of individual tubes outside of the batch scanning environment.

The configuration of the identification system 128 ensures that each NMR tube 100 maintains a unique and persistent identity throughout the workflow. Because the first machine-readable identifier 132 is embedded within the elongated body 104 of the NMR tube 100, the identifier remains associated with the tube regardless of handling, transfer between systems, or removal of auxiliary components. This persistent identification improves traceability and supports chain-of-custody requirements.

The system 600 is compatible with automated sample handling systems, including automated sample changers used in NMR spectroscopy. The standardized dimensions and arrangement of the NMR tubes 100 within the support structure 500 enable integration with existing laboratory equipment. The ability to perform batch identification and tracking enhances the efficiency and reliability of automated workflows.

Overall, the system-level implementation of the identification system 128 enables scalable, high-throughput identification and tracking of NMR tubes 100. The combination of batch scanning capability, automated data processing, and persistent embedded identifiers provides a comprehensive solution for managing large numbers of samples in modern analytical laboratories.

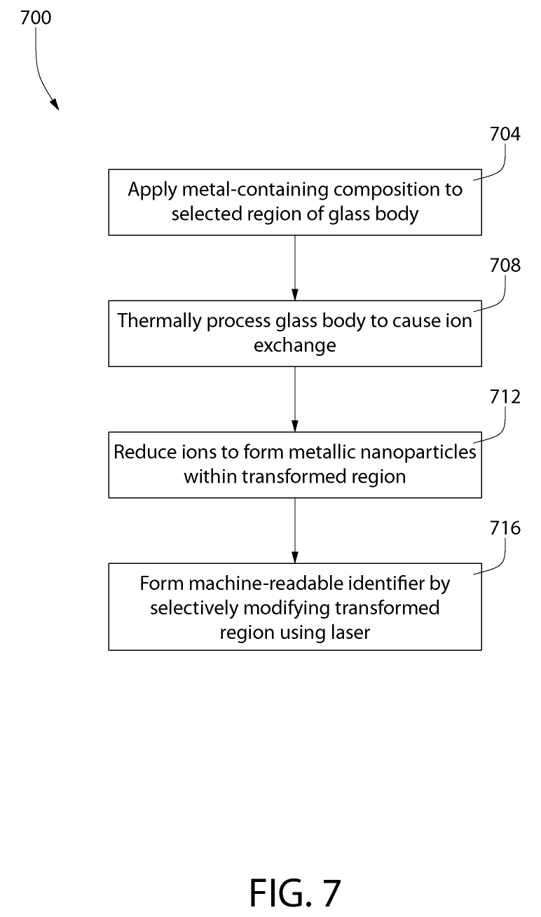

Referring now to FIG. 7, a method 700 of manufacturing the NMR tube 100 having the first machine-readable identifier 132 is illustrated. The method 700 comprises a series of steps for forming the transformed region 140 within the elongated body 104 and forming the first machine-readable identifier 132 within the transformed region 140. The method 700 includes a step 704 of applying a metal-containing composition to at least a portion of the elongated body 104. The metal-containing composition is applied to a surface region corresponding to a desired location of the transformed region 140, including the distal end face 136 and, in some embodiments, one or more sidewall regions of the elongated body 104.

The metal-containing composition comprises a source of metallic ions capable of diffusing into the glass matrix of the elongated body 104. In some embodiments, the metal-containing composition comprises a silver-containing composition. In some embodiments, the metal-containing composition comprises a suspension of metal particles in a carrier medium. The metal-containing composition is applied using a controlled deposition process to achieve uniform coverage of the selected region.

In step 708, the elongated body 104 is thermally processed after application of the metal-containing composition. The thermal processing is performed at a temperature and for a duration sufficient to initiate ion exchange between the metallic ions in the metal-containing composition and ions present in the glass matrix of the elongated body 104.

During step 708, the metallic ions diffuse into the glass matrix and replace native ions, thereby forming the transformed region 140 within the elongated body 104. In some embodiments, the thermal processing is performed in a controlled environment, such as a furnace or kiln, to achieve consistent ion exchange. In some embodiments, the thermal processing results in volatilization of carrier materials associated with the metal-containing composition.

In step 712 the ions within the transformed region 140 are reduced to form metallic nanoparticles within the glass matrix. The reduction process is controlled to achieve a desired distribution and density of metallic nanoparticles within the transformed region 140, thereby modifying the optical properties of the transformed region 140.

In some embodiments, the step 712 comprises thermally reducing the ions. In other embodiments, the step 712 comprises exposing the elongated body 104 to a chemical reducing environment. The reduction process is controlled to maintain the structural integrity of the elongated body 104 while producing the desired optical absorption characteristics of the transformed region 140.

In step 716, the first machine-readable identifier 132 is formed within the transformed region 140 by selectively modifying portions of the transformed region 140. The selective modification produces a pattern of regions having differing optical properties that collectively define the first machine-readable identifier 132.

In some embodiments, the step 716 comprises directing a laser toward the transformed region 140 to selectively modify the transformed region 140. In some embodiments, the laser comprises an ultraviolet (UV) laser. In other embodiments, the laser comprises an infrared (IR) laser, a green laser, an excimer laser, or another laser system selected based on interaction with the transformed region 140.

In some embodiments, the step 716 comprises selectively removing portions of the transformed region 140 to create high-contrast features defining the first machine-readable identifier 132. In other embodiments, the step 716 comprises modifying portions of the transformed region 140 without complete material removal.

The energy applied during the step 716 is selected such that the transformed region 140 absorbs the energy and enables localized modification without introducing structural defects into the elongated body 104. In some embodiments, the energy level is lower than that required for marking untreated glass due to the enhanced absorption characteristics of the transformed region 140.

The step 716 is performed such that the resulting first machine-readable identifier 132 is spectroscopically non-interfering with NMR measurements performed on a sample contained within the tube cavity 124. The selective modification preserves the structural continuity of the elongated body 104 and avoids the formation of discontinuities that could affect NMR performance.

In some embodiments, the method may be performed in an automated production process. The application, thermal processing, reduction, and identifier formation steps are integrated into a production line to enable consistent and repeatable manufacturing of a plurality of NMR tubes 100.

In some embodiments, the method 700 further comprises forming one or more additional machine-readable identifiers, including the second machine-readable identifier 144, on the elongated body 104. In some embodiments, the additional identifiers are formed using the same process as the first machine-readable identifier 132. In other embodiments, the additional identifiers are formed using alternative techniques.

The method 700 produces an NMR tube 100 having a permanently integrated machine-readable identifier 132 with enhanced durability, optical contrast, and compatibility with NMR spectroscopy. The resulting NMR tube 100 is suitable for use in high-throughput analytical environments and automated workflows.

While the invention has been described with respect to specific examples including presently preferred modes of carrying out the invention, those skilled in the art will appreciate that there are numerous variations and permutations of the above described systems and techniques. It is to be understood that other embodiments may be utilized and structural and functional modifications may be made without departing from the scope of the present invention. Thus, the spirit and scope of the invention should be construed broadly as set forth in the appended claims.

The present disclosure encompasses a variety of embodiments relating to NMR tubes, systems for identifying NMR tubes, methods of identifying NMR tubes, and methods of manufacturing NMR tubes having machine-readable identifiers. The following exemplary embodiments are provided to illustrate various aspects of the present disclosure and are not intended to limit the scope of the invention.

In some embodiments, an NMR tube comprises an elongated glass body extending from a proximal end to a distal end and a first machine-readable identifier formed within a transformed region of the glass body. The transformed region comprises a portion of the glass body that has undergone ion exchange to incorporate metallic ions into the glass body, and the first machine-readable identifier is integral with the glass body.

In some embodiments, the first machine-readable identifier is configured to be spectroscopically non-interfering with NMR measurements performed on a sample contained within the NMR tube. In some embodiments, the first machine-readable identifier does not produce a detectable artifact during operation of an NMR spectrometer.

In some embodiments, the first machine-readable identifier is disposed on a distal end face of the glass body, the distal end face forming a bottom surface of the NMR tube. In some embodiments, the distal end face is substantially planar, and the first machine-readable identifier is positioned at a central portion of the distal end face.

In some embodiments, the first machine-readable identifier is configured to enable simultaneous scanning of a plurality of NMR tubes. In some embodiments, the first machine-readable identifier comprises a two-dimensional code, including a data matrix barcode. In some embodiments, the first machine-readable identifier comprises a one-dimensional barcode.

In some embodiments, the NMR tube further comprises a second machine-readable identifier disposed on a sidewall of the glass body. In some embodiments, the second machine-readable identifier is configured for individual scanning and is positioned adjacent to the proximal end. In some embodiments, the first and second machine-readable identifiers encode identical information corresponding to the NMR tube.

In some embodiments, the first machine-readable identifier is non-removably integrated with the glass body and is resistant to degradation upon exposure to solvents, including chloroform, acetone, and dimethyl sulfoxide. In some embodiments, the glass body comprises borosilicate glass or fused silica.

In some embodiments, the metallic ions incorporated into the glass body comprise silver ions. In some embodiments, the transformed region comprises metallic nanoparticles within the glass body. In some embodiments, the transformed region extends to a depth in a range from about 5 microns to about 100 microns.

In some embodiments, the transformed region exhibits enhanced absorption of electromagnetic radiation, including ultraviolet radiation, relative to untreated glass. In some embodiments, the first machine-readable identifier is formed by selectively removing portions of the transformed region. In some embodiments, the portions of the transformed region are removed by laser ablation.

In some embodiments, a system for identifying NMR tubes comprises a plurality of NMR tubes and a scanning device configured to read machine-readable identifiers from distal end faces of the plurality of NMR tubes while the NMR tubes are arranged in a common orientation. In some embodiments, the NMR tubes are arranged in a multi-position tray. In some embodiments, the scanning device comprises an optical scanner configured to simultaneously read the identifiers from a common viewpoint.

In some embodiments, the system further comprises a database configured to associate each machine-readable identifier with sample information corresponding to a respective NMR tube. In some embodiments, the system further comprises a laboratory information management system configured to track samples based on the machine-readable identifiers.

In some embodiments, a method of identifying a plurality of NMR tubes comprises providing a plurality of NMR tubes having machine-readable identifiers, arranging the NMR tubes such that distal end faces are oriented in a common direction, and simultaneously scanning the machine-readable identifiers from the distal end faces using a scanning device. In some embodiments, the NMR tubes are arranged in a multi-position tray. In some embodiments, the method further comprises associating the scanned identifiers with sample information stored in a database or laboratory information management system.

In some embodiments, a method of manufacturing an NMR tube having a machine-readable identifier comprises applying a metal-containing composition to a surface of a glass body, thermally processing the glass body to cause ions of the metal composition to diffuse into the glass body via ion exchange, reducing the ions within the glass body to form metallic nanoparticles and thereby form a transformed region within the glass body, and forming a machine-readable identifier within the transformed region by selectively modifying the transformed region.

In some embodiments, the transformed region exhibits enhanced absorption of laser radiation relative to untreated glass. In some embodiments, the metallic nanoparticles are formed through reduction of silver ions. In some embodiments, the transformed region is formed to a controlled depth in a range from about 5 microns to about 100 microns.

In some embodiments, forming the machine-readable identifier comprises removing portions of the transformed region to create high-contrast markings. In some embodiments, forming the machine-readable identifier is performed without introducing structural defects in the glass body. In some embodiments, forming the machine-readable identifier comprises selectively ablating portions of the transformed region using a laser, including an ultraviolet laser, operating at reduced energy relative to untreated glass.

In some embodiments, a container for storing a sample comprises a body formed of a substrate material and a machine-readable identifier formed within a transformed region of the substrate material. The transformed region comprises a region of the substrate material that has undergone ion exchange to incorporate metallic ions into the substrate material and contains metallic nanoparticles within the substrate material.

In some embodiments, the substrate material comprises glass. In some embodiments, the machine-readable identifier is integral with the substrate material and is resistant to degradation upon exposure to solvents. In some embodiments, the transformed region exhibits enhanced absorption of electromagnetic radiation. In some embodiments, the machine-readable identifier is formed by selective removal of portions of the transformed region to create a machine-readable pattern. In some embodiments, the machine-readable identifier does not produce a detectable artifact during spectroscopic analysis.

1. A nuclear magnetic resonance (NMR) tube, comprising:
a glass body extending from a proximal end to a distal end; and
a first machine-readable identifier formed within a transformed region at the distal end of the glass body;
wherein the transformed region comprises a portion of the glass body that has undergone ion exchange to incorporate metallic ions into the glass body,
wherein the first machine-readable identifier is integral with the glass body; and
wherein the first machine-readable identifier is configured to be spectroscopically non-interfering with NMR measurements performed on a sample contained within the NMR tube.

2. The NMR tube of claim 1, wherein the first machine-readable identifier is not detectable by an NMR spectrometer during operation.

3. The NMR tube of claim 1, wherein the first machine-readable identifier is disposed on a distal end face of the glass body, the distal end face forming a bottom surface of the NMR tube.

4. The NMR tube of any one of claim 1, wherein the distal end face is planar.

5. The NMR tube of any one of claim 1, wherein the first machine-readable identifier comprises a two-dimensional code.

6. The NMR tube of claim 5, wherein the two-dimensional code comprises a data matrix barcode.

7. The NMR tube of any one of claim 1, further comprising a second machine-readable identifier disposed on a sidewall of the glass body.

8. The NMR tube of any one of claim 7, wherein the first machine-readable identifier and the second machine-readable identifier encode identical information corresponding to the NMR tube.

9. The NMR tube of any one of claim 1, wherein the metallic ions comprise silver ions.

10. The NMR tube of any one of claim 1, wherein the transformed region comprises metallic nanoparticles within the glass body.

11. A system for identifying nuclear magnetic resonance (NMR) tubes, comprising:
a plurality of NMR tubes according to claim 1; and
a scanning device configured to read the first machine-readable identifiers from the distal end faces of the plurality of NMR tubes while the plurality of NMR tubes remain arranged in a common orientation.

12. The system of claim 11, wherein the plurality of NMR tubes are arranged in a multi-position tray.

13. The system of claim 11, wherein the scanning device comprises an optical scanner configured to simultaneously read the first machine-readable identifiers from a common viewpoint.

14. A method of identifying a plurality of nuclear magnetic resonance (NMR) tubes, comprising:
providing a plurality of NMR tubes according to claim 1;
arranging the plurality of NMR tubes such that the distal end faces of the plurality of NMR tubes are oriented in a common direction; and
simultaneously scanning first machine-readable identifiers of the plurality of NMR tubes from the distal end faces using a scanning device.

15. The method of claim 14, wherein the plurality of NMR tubes are arranged in a multi-position tray.

16. A method of manufacturing a nuclear magnetic resonance (NMR) tube having a machine-readable identifier, comprising:
applying a metal-containing composition to a surface of a glass body of the NMR tube;
thermally processing the glass body to cause ions of the metal composition to diffuse into the glass body via ion exchange;
reducing the ions within the glass body to form metallic nanoparticles and thereby form a transformed region within the glass body; and
forming a machine-readable identifier within the transformed region by selectively modifying the transformed region such that the machine-readable identifier is spectroscopically non-interfering with NMR measurements performed on a sample contained within the NMR tube.

17. The method of claim 16, wherein forming the machine-readable identifier comprises selectively ablating portions of the transformed region using a laser.

18. The method of claim 16, wherein the laser comprises an ultraviolet laser.

19. The method of claim 16, wherein the laser operates at reduced energy relative to untreated glass of the glass body.

20. A container for storing a sample, comprising:
a body formed of a substrate material; and
a machine-readable identifier formed within a transformed region of the substrate material,
wherein the transformed region comprises a region of the substrate material that has undergone ion exchange to incorporate metallic ions into the substrate material and contains metallic nanoparticles within the substrate material, and
wherein the machine-readable identifier is integral with the substrate material and is resistant to degradation upon exposure to solvents.
